(19) United States
(12) Patent Application Publication
(10) Pub. No.: US 2012/0235596 A1
(43) Pub. Date: Sep. 20, 2012

(54) LED DRIVERS WITH AUDIBLE NOISE ELIMINATION AND ASSOCIATED METHODS

(76) Inventors: Kaiwei Yao, San Jose, CA (US); Zheng Lou, Santa Clara, CA (US)

(21) Appl. No.: 13/051,498

(22) Filed: Mar. 18, 2011

(51) Int. Cl. H05B 37/02; H05K 13/00

(52) U.S. Cl. 315/294; 29/592.1

(57) ABSTRACT

The present technology provides LED drivers with audible noise elimination and methods thereof. A burst dimming signal is used in the LED driver. A switch is serially coupled to the output capacitor of the LED driver and controlled by the burst dimming signal for eliminating any audible noise.

### TECHNICAL FIELD

The present technology generally relates to LED drivers, and more particularly, to LED drivers with burst dimming.

### BACKGROUND

Burst dimming is often used in an LED driver to adjust the luminance of the LED. A burst dimming signal, e.g., a pulse width modulation (PWM) signal, can be used to control the on and off operation of an LED driver. The LED driver operates normally when the burst dimming signal is valid (high level “1”, or low level “0”), and is shut down when the burst dimming signal is invalid (low level “0”, or high level “1”). The lower limit of the burst frequency is approximately 120 Hz, below which the eye no longer blends the pulses into a perceived continuous light. The upper limit is determined by a required minimum contrast ratio.

Typically, an LED driver comprises an output capacitor connected between its output terminals, so as to filter the AC current ripple of the output current. The output capacitor is charged and discharged at the burst dimming frequency when the LED driver is on and off under the control of the burst dimming signal. Thus an audible noise is generated.

A prior solution to eliminate the audible noise includes serially coupling a switch to the LED or LED string, such as shown in FIG. 1. The switch S2 is turned on when the burst dimming signal is on, and turned off when the burst dimming signal is off. So the output capacitor Cₒᵤₜ is not discharged during the dimming off period. The voltage across the output capacitor Cₒᵤₜ is maintained and the audible noise is eliminated. However, the current flowing through the switch S2 during the dimming on period is equal to the current flowing through the LED, which may be up to several amperes. Thus, the conduction loss of the switch S2 can be large enough to reduce the efficiency of the LED driver.

### BRIEF DESCRIPTION OF THE DRAWINGS

The present technology can be further understood with reference to the following detailed description and the appended drawings. Like elements are identified with like reference numerals.

FIG. 1 illustrates an LED driver with a conventional audible noise elimination technique.

FIG. 2 is the block diagram of an LED driver with audible noise elimination in accordance with embodiments of the present technology.

FIG. 3 illustrates an LED driver with audible noise elimination in accordance with embodiments of the present technology.

FIG. 4 illustrates an LED driver with audible noise elimination in accordance with additional embodiments of the present technology.

FIG. 5 is an implementation example of the LED driver shown in FIG. 4.

FIG. 6 is the flow chart of an LED driving method with audible noise elimination in accordance with embodiments of the present technology.

### DETAILED DESCRIPTION

Various embodiments of LED drivers and associated methods are described below. In the following detailed description of the present technology, numerous specific details are set forth in order to provide a thorough understanding of the present technology. However, it will be obvious to one of ordinary skill in the art that the present technology may be practiced without these specific details. In other instances, well-known methods, procedures, components, and circuits have not been described in detail so as not to unnecessarily obscure aspects of the present technology. A person skilled in the relevant art will also understand that the technology may have additional embodiments, and that the technology may be practiced without several of the details of the embodiments described below with reference to FIGS. 2-6.

FIG. 2 is a block diagram of an LED driver with audible noise elimination in accordance with embodiments of the present technology. As shown in FIG. 2, the LED driver comprises a power converter 201, an output capacitor Cₒᵤₜ and a switch Sₒᵤₜ. The power converter 201 provides a driving signal to the LEDs under the control of a burst dimming signal. The power converter 201 operates normally when the burst dimming signal is valid, and is shut down when the burst dimming signal is invalid. The power converter may be a linear regulator, a charge pump, or a switching regulator. It can be used to drive a single LED, a single LED string, or multiple LED strings. In one embodiment, the current flowing through the LED is fed back to control the power converter under normal operation. In another embodiment, a current balance circuit is used to balance the current flowing through multiple LED strings. The voltage across the current balance circuit is fed back to control the power converter under normal operation.

The output capacitor Cₒᵤₜ is electrically coupled between the output terminals of the power converter 201 to filter the AC current ripple of the output current. The switch Sₒᵤₜ is serially connected to the output capacitor Cₒᵤₜ, and controlled by the burst dimming signal. The switch Sₒᵤₜ is turned on when the burst dimming signal is valid, and turned off when the burst dimming signal is invalid. Since the switch Sₒᵤₜ is turned off when the burst dimming signal is invalid, the output capacitor Cₒᵤₜ is not discharged. So the audible noise can be eliminated.

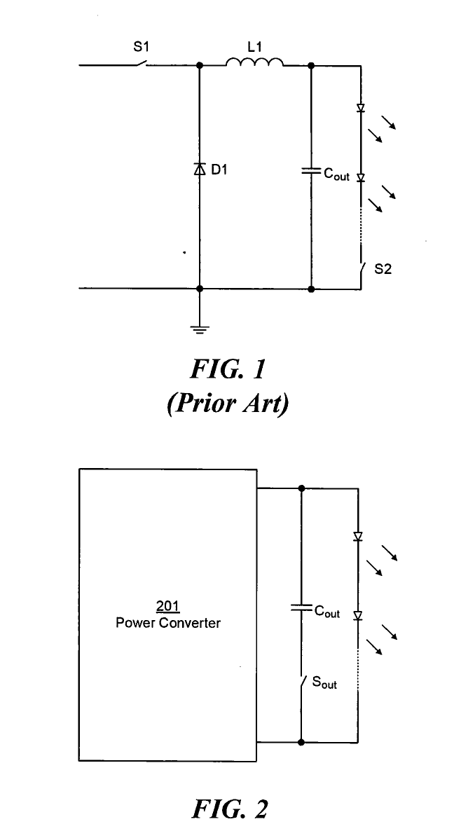

In the prior art LED driver shown in FIG. 1, the conduction loss of the switch S2 can be calculated as I_{LED}²*R_{dson2}, where I_{LED} is the load current flowing through the LEDs, and R_{dson2} is the on resistance of the switch S2. In the LED driver shown in FIG. 2, the conduction loss of the switch Sₒᵤₜ can be calculated as I_{C}²*R_{dson}, where I_{C} is the RMS value of the current flowing through the output capacitor Gₒᵤₜ, and R_{dson} is the on resistance of the switch Sₒᵤₜ. Assuming that all AC current flows through the output capacitor Cₒᵤₜ, the current I_{C} is the same as the ripple current of the inductor whose magnitude is normally designed as 20% to 40% of the load current. If R_{dson}=R_{dson2}, the conduction loss of the switch S2 can be 11˜45 times larger than that of the switch Sₒᵤₜ. As a result, the efficiency of the LED driver can be enhanced through serially connecting the switch to the output capacitor instead of the LEDs.

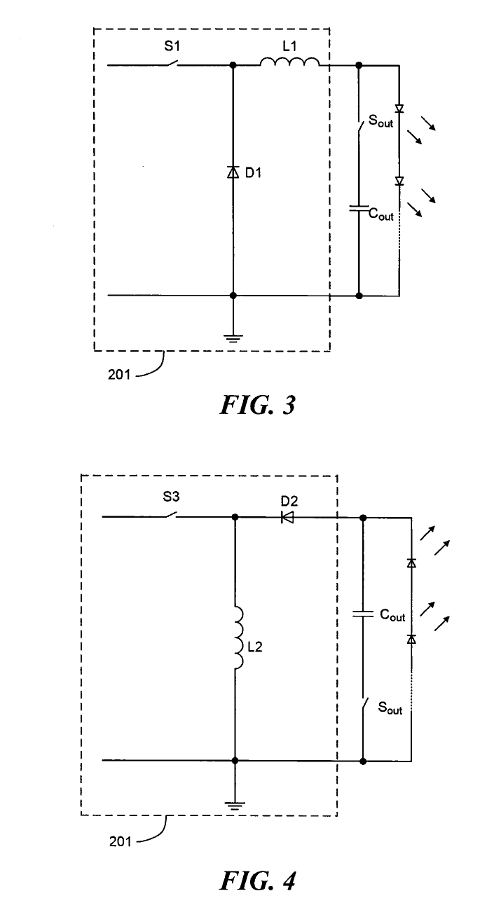

FIG. 3 illustrates an LED driver with audible noise elimination in accordance with embodiments of the present technology. The power converter 201 is a buck converter comprising a switch S1, a diode D1 and an inductor L1. The output capacitor Cₒᵤₜ is electrically connected between the switch Sₒᵤₜ and the ground. In one embodiment, the diode D1 is replaced by a synchronous switch.

FIG. 4 illustrates an LED driver with audible noise elimination in accordance with additional embodiments of the present technology. The power converter 201 is a buck-boost converter comprising a switch S3, an inductor L2 and a diode D2. The switch Sₒᵤₜ is electrically connected between the output capacitor Cₒᵤₜ and the ground. Since one terminal of the switch Sₒᵤₜ is grounded, the driving of the switch Sₒᵤₜ can be simple, low cost and can be easily integrated into an integrated circuit.

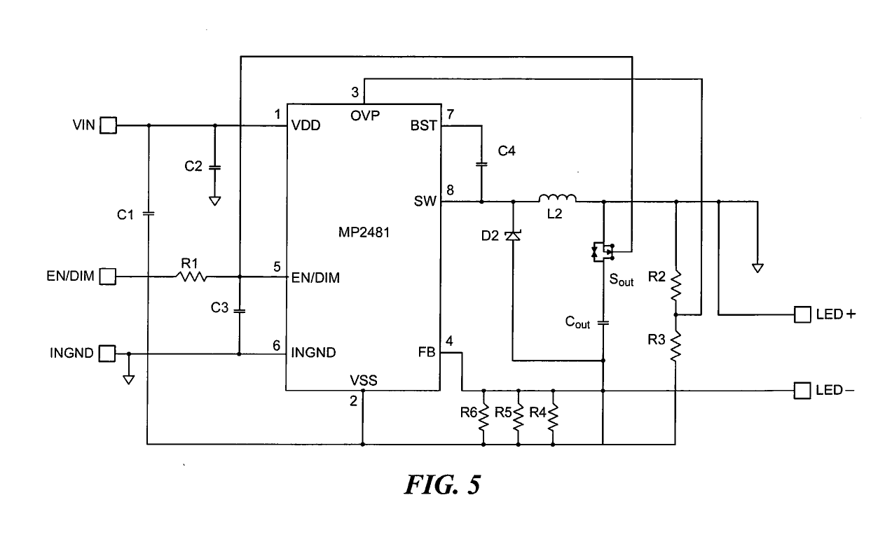

FIG. 5 is an implementation example of the LED driver shown in FIG. 4. MP2481 is a power management IC comprises the switch S3, and the control, driving and protection circuit of the switch S3. The burst dimming signal which comes from the EN/DIM pin is directly used to control the switch Sₒᵤₜ.

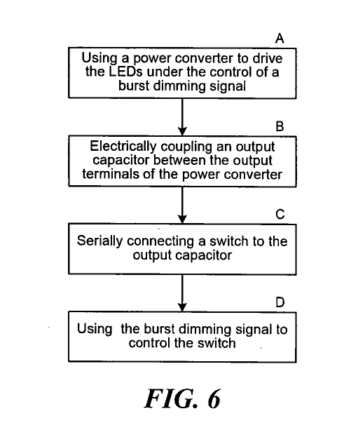

FIG. 6 is the flow chart of an LED driving method with audible noise elimination in accordance with one embodiment of the present technology. At stage A, a power converter is used to drive the LEDs under the control of a burst dimming signal. The power converter operates normally when the burst dimming signal is valid, and is shut down when the burst dimming signal is invalid. The power converter may be a linear regulator, a charge pump, or a switching regulator. It can be used to drive a single LED, a single LED string, or multiple LED strings. At stage B, an output capacitor is electrically coupled between the output terminals of the power converter to filter the AC current ripple of the output current. At stage C, a switch is serially connected to the output capacitor. At stage D, the burst dimming signal is used to control the switch. The switch is turned on when the burst dimming signal is valid, and turned off when the burst dimming signal is invalid. Since the switch is turned off when the burst dimming signal is invalid, the output capacitor is not discharged, and thus the audible noise can be eliminated.

From the foregoing, it will be appreciated that specific embodiments of the technology have been described herein for purposes of illustration, but that various modifications may be made without deviating from the disclosure. In addition, many of the elements of one embodiment may be combined with other embodiments in addition to or in lieu of the elements of the other embodiments. Accordingly, the disclosure is not limited except as by the appended claims.

I/we claim:

1. A light emitting diode (LED) driver, comprising:
a power converter configured to provide a driving signal to a plurality of LEDs under the control of a burst dimming signal, the power converter having a plurality of output terminals;
an output capacitor electrically coupled between output terminals of said power converter;
a switch serially connected to said output capacitor; and
wherein an on/off operation of said switch is controlled by said burst dimming signal.

2. The LED driver of claim 1, wherein said power converter operates normally when said burst dimming signal is valid, and is shut down when said burst dimming signal is invalid.

3. The LED driver of claim 2, wherein said switch is turned on when said burst dimming signal is valid, and turned off when said burst dimming signal is invalid.

4. The LED driver of claim 1, wherein said switch is electrically connected between said output capacitor and the ground.

5. The LED driver of claim 1, wherein said power converter is a switching regulator.

6. A method for assembling light emitting diodes (LEDs), the method comprising:
electrically coupling a plurality of LEDs with a plurality of output terminals of a power converter, the power converter being configured to operate under control of a burst dimming signal;
electrically coupling an output capacitor between the output terminals of said power converter;
serially connecting a switch to said output capacitor; and
wherein said switch is configured to be controlled by said burst dimming signal to eliminate audible noise.

7. The method of claim 6, wherein said power converter operates normally when said burst dimming signal is valid, and is shut down when said burst dimming signal is invalid.

8. The method of claim 7, wherein said switch is turned on when said burst dimming signal is valid, and turned off when said burst dimming signal is invalid.

9. The method of claim 6, wherein said switch is electrically connected between said output capacitor and the ground.

10. The method of claim 6, wherein said power converter is a switching regulator.

11. A method for driving light emitting diodes (LEDs), the method comprising:
driving said plurality of LEDs with a power converter, said LEDs being electrically coupled to a plurality of output terminals of said power converter, an output capacitor being coupled between said output terminals of said power converter, and a switch being serially connected to said output capacitor;
controlling said power converter with a burst dimming signal; and controlling said switch with said burst dimming signal to eliminate audible noise.

12. The method of claim 11, wherein controlling said power converter includes:
operating said power converter normally when said burst dimming signal is valid; and
shutting down said power converter when said burst dimming signal is invalid.

13. The method of claim 11, wherein:
controlling said power converter includes (a) operating said power converter normally when said burst dimming signal is valid and (b) shutting down said power converter when said burst dimming signal is invalid; and
controlling said switch includes (a) turning on said switch when said burst dimming signal is valid and (b) turning off said switch when said burst dimming signal is invalid.

14. The method of claim 11, wherein controlling said switch includes turning off said switch when said power converter is shut down.

15. The method of claim 11, wherein controlling said switch includes preventing said output capacitor from discharging when said burst dimming signal is invalid.
